(19) United States
(12) Patent Application Publication
(10) Pub. No.: US 2004/0188858 A1
(43) Pub. Date: Sep. 30, 2004

(54) Semiconductor device and method of wire bonding for semiconductor device

(75) Inventor: Yoshifumi Watanabe, Kariya-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/795,318

(22) Filed: Mar. 9, 2004

(30) Foreign Application Priority Data
Mar. 28, 2003 (JP) 2003-090973

(51) Int. Cl. H01L 23/495

(52) U.S. Cl. 257/779

(57) ABSTRACT

In a semiconductor device and a method of wire bonding for the semiconductor device according to the invention, a semiconductor chip and a lead frame insert-molded into a package are connected to each other by a gold bonding wire by means of a wire bonding process, in which a combination of ultrasonic wave bonding and thermal compression bonding is carried out. A pre-bonding portion is formed at first on a bonding surface of the lead frame, and then the bonding wire is bonded to the semiconductor chip and to such pre-bonding portion by the combination of the ultrasonic wave bonding and the thermal compression bonding, so that the bonding wire is firmly connected to the lead frame through the pre-bonding portion.

### CROSS REFERENCE TO RELATED APPLICATION

This application is based on Japanese Patent Application No. 2003-090973 filed on Mar. 28, 2003, the disclosures of which are incorporated herein by reference.

### FIELD OF THE INVENTION

The present invention relates to a semiconductor device and a method of wire bonding for the semiconductor device, and more particularly to a semiconductor device and a method of wire bonding for the semiconductor device, in which a lead frame is insert-molded within a package of synthetic resin, a semiconductor chip is mounted in the package and a gold bonding wire is connected to an electrode of the semiconductor chip and the lead frame by a wire bonding process.

### BACKGROUND OF THE INVENTION

In a conventional semiconductor device, for example a semiconductor pressure sensor device, a part of which is schematically shown in FIG. 9, a lead frame (1) is insert-molded in a package (2) of a synthetic resin, a semiconductor (pressure sensor) chip (3) is mounted on the package (2) by means of an adhesive material, and a bonding wire (4), for example made of a gold wire, is connected to an electrode of the semiconductor chip (3) and a front surface of the lead frame (1). An aluminum wire is generally used as the bonding wire for the semiconductor device. A gold wire is, however, often used as the bonding wire for the semiconductor device, for example a semiconductor pressure sensor device for detecting an intake air pressure for an internal combustion engine, which is used in an atmosphere of exhaust gas of the engine.

When the lead frame is insert-molded in the package of the synthetic resin, a front surface of the lead frame to which the bonding wire is later connected is often contaminated by a molding process, namely the surface may be contaminated with resin gas, mold release agent or oil on a surface of mold dies, and so on. The contamination on the bonding surface adversely affects a stable juncture between the surface of the lead frame and the bonding wire.

Therefore, in the conventional semiconductor device, such as the semiconductor device described in U.S. Pat. No. 6,172,424, a front and a back surface of a lead frame, to which (the front surface) a bonding wire is later connected, is tightly held by a pair of protruded portions of upper and lower mold dies, so that both of the front and back surfaces tightly held by the mold dies are kept free from the contamination.

As shown in FIG. 9, however, a concave (2a) remains at the back side of the package (2) after the resin molding is completed. It is, therefore, necessary to fill the concave (2a) with the same or similar resin by a potting method and so on, which makes more complicated a method of manufacturing the semiconductor device and makes the manufacturing steps higher in cost.

In a case in which an aluminum wire is used as the bonding wire, the wire bonding method of ultrasonic wave is generally adopted, so that the bonding wire is vibrated by the ultrasonic waves generating a friction therebetween, and that the friction heat applied to the bonding wire and lead frame causes a juncture thereof and additionally removes the contamination on the front bonding surface of the lead frame. Accordingly, the juncture of the bonding wire and the lead frame may not cause a problem in terms of its juncture strength. On the other hands, when a gold wire is used as the bonding wire, the wire bonding method of ultrasonic wave is additionally used to the thermal compression bonding, which is a main bonding method for the gold wire. And therefore, it may not be largely expected that the contamination on the lead frame will be removed by the ultrasonic wave vibration.

### SUMMARY OF THE INVENTION

In view of the above problem, it is an object of the present invention to provide a semiconductor device and a method of wire bonding for the semiconductor device, in which a stable and firm juncture of a bonding wire of a gold wire to a lead frame is obtained and such device is manufactured at a lower cost

The inventors of the present invention made a study for increasing juncture strength between the bonding wire of gold wires and the lead frame, in which three different wire bonding methods were reviewed and evaluated. The detail of the study will be explained below, however, the three methods are (i) a method of reducing the contamination on the lead frame during an insert-molding process, (ii) a method of removing the contamination from the lead frame after the insert-molding process, and (iii) a method of increasing juncture strength by changing conditions of the wire bonding of ultrasonic wave. As a result, the inventors came to a conclusion that a method of pre-ball wire bonding according to the present invention is most effective when compared with those three different methods, in which a pre-ball (a pre-bonding portion) is formed on a surface of a lead frame to which a bonding wire of gold wires is connected.

According to a feature of this invention, a method of wire bonding for a semiconductor device, in which a gold bonding wire is connected at its one end to an electrode of semiconductor chip and at its other end to a lead frame insert-molded into a package, comprises a step of forming a pre-ball from the gold bonding wire, a step of pressing to the lead frame and cutting the pre-ball from the bonding wire so as to form a pre-bonding portion on the surface of the lead frame, a step of bonding one end of the bonding wire to the electrode of the semiconductor chip, and then a step of bonding the other end of the bonding wire to the pre-bonding portion.

A semiconductor device according to a feature of this invention, comprises a semiconductor package made of a resin into which a lead frame is insert-molded, a semiconductor chip mounted on the package, a pre-bonding portion made of gold formed on a surface of the lead frame and a gold bonding wire bonded at its one end to an electrode of the semiconductor chip and bonded at its other end to the pre-bonding portion.

According to the above semiconductor device and the method of wire bonding for the semiconductor device, in which one end of the gold bonding wire is connected to the pre-bonding portion, high juncture strength between the bonding wire and the lead frame can be achieved. Furthermore, the pre-bonding portion can be formed on the surface of the lead frame, an area of which is larger than an area which is made by a direct bonding of the bonding wire to the lead frame, so that a sufficient juncture strength can be obtained even in a case that there is contamination on the surface of the lead frame at the wire bonding.

Furthermore, the pre-ball (pre-bonding portion) can be formed by a standard machine for the wire bonding, and therefore the process of forming the pre-ball and pre-bonding portion may not lead to an increase of a manufacturing cost, in particular compared with a case in which a concave made in the package during the insert-molding will be afterwards filled with a resin by a potting process.

In the present invention, it is also possible to provide a step of rinsing out contamination on the surface of the lead frame before the step of forming the pre-bonding portion thereon. According to this process, the juncture strength between the bonding wire and the lead frame can be further increased. Since a back surface of the lead frame is covered by the resin when the lead frame is insert-molded to the package, a high reliability of an insulation performance and/or corrosion resistance can be achieved.

### BRIEF DESCRIPTION OF THE DRAWINGS

The above and other objects, features and advantages of the present invention will become more apparent from the following detailed description made with reference to the accompanying drawings. In the drawings:

FIG. 1A is a schematic cross-sectional view showing a part of a pressure sensor device according to the present invention;

FIG. 1B is an enlarged cross-sectional view showing a pre-bonding portion;

FIG. 2 is a schematic cross-sectional view showing insert-molding dies for a package;

FIG. 3A is a schematic cross-sectional view showing a process of forming a pre-bonding portion;

FIG. 3B is a schematic cross-sectional view showing a process of a wire bonding process for bonding a wire to the pre-bonding portion;

FIG. 4 is a graph showing breaking strength of those samples, in which the bonding wires are bonded to the lead frame before and after the lead frame is insert-molded and the samples in which the bonding wires are bonded to the lead frames after the pre-ball bonding according to the present invention is done;

FIGS. 5 to 7 are schematic cross-sectional views showing insert-molding dies, which are considered by the inventors during a course of this invention;

FIG. 8 is a graph showing breaking strength of those samples, for which wire bonding processes of various kinds of conditions are applied; and

FIG. 9 is a schematic cross-sectional view showing a part of a prior art semiconductor device.

### DETAILED DESCRIPTION OF THE PREFERRED EMBODIMENTS

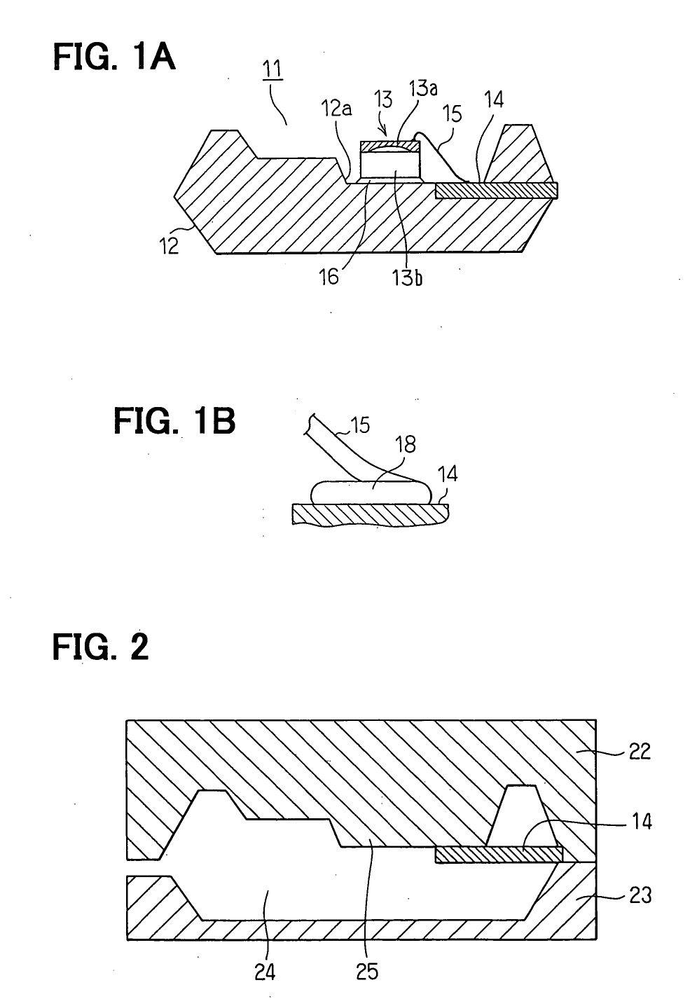

A semiconductor pressure sensor device 11 will be explained with reference to FIGS. 1 to 4, which is used for an internal combustion engine for detecting an intake air pressure for the engine. A semiconductor pressure sensor chip 13 (hereinafter simply referred to as a semiconductor chip) is mounted on a package 12 made of a resin, into which a lead frame 14 of conductive material is insert-molded. A bonding wire 15 made of gold wires is connected at its one end to an electrode of the semiconductor chip 13 and also connected at its other end to a front (bonding) surface of the lead frame 14.

The package 12 is made of an epoxy resin, or a heat resistant resin such as poly-buthylene terephthalate (i.e., PBT) or poly-phenylene sulfide (i.e., PPS). As shown in FIG. 2, the lead frame 14 is held by an upper and a lower mold dies 22 and 23 and a cavity 24 is formed by the dies 22 and 23, to which a resin will be injected. At an inner surface of the upper die 22, a projected portion 25 is formed, so that a recess 12a is formed in the package 12 after the insert-molding process is completed. As mentioned above, the semiconductor chip 13 is mounted in this recess 12a and a part of the front surface of the lead frame 14 is exposed to a space formed by the recess 12a. As seen from FIG. 1A, a back surface of the lead frame 14 is completely covered with the resin.

The semiconductor chip 13 is formed with a diaphragm of a thin film at a central portion of single crystal silicon 13a, which receives a pressure of a measuring object, such as an intake air for an engine (not shown) and will be elastically deformed by the pressure. Four piezoelectric resistors are formed with a bridge connection on the surface of this diaphragm. The silicon chip 13a of the above structure is adhered to a base 13b by a glass bonding method or the like. On the top surface of the silicon chip 13a, four electrodes are formed (at the right hand side of FIG. 1A). The semiconductor chip 13 made of the silicon chip 13a and the base 13b is then adhered to the recess 12a of the package 12 by means of adhesive material 16.

Each of the electrodes of the silicon chip 13a is connected to the respective lead frames 14 through bonding wires 15, by a wire bonding process of a combination of an ultrasonic wave bonding and a thermal compression bonding. A sensor protection material (not shown), such as silicon gel, is embedded in the recess 12a, so that semiconductor chip 13, the lead frames 4 and the bonding wires 15 are covered with the protection material for protecting them from being directly exposed to the atmosphere, or the intake air in its operation.

A wire bonding machine (not shown) has a bonding station at which the package 12 is held at a desired position, an image recognition device for recognizing the position of the electrodes of the semiconductor chip 13 and the position of the lead frames 14, a bonding head, a table for moving the bonding head in directions of X-axis and Y-axis, a heat block for heating a work (the bonding wire) and an electronic control unit for controlling the operation of this machine.

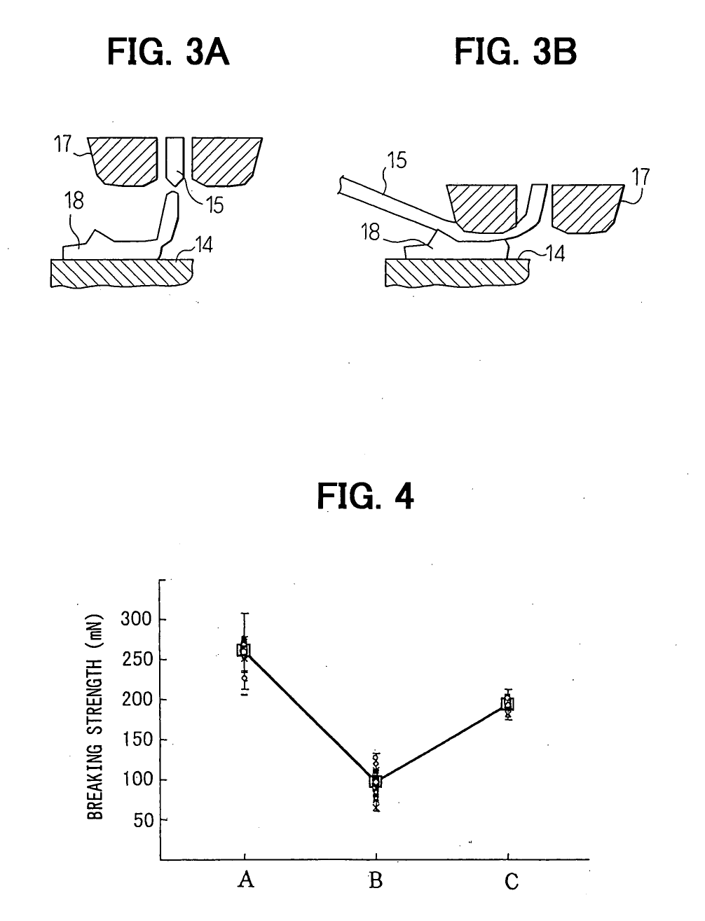

The bonding head (not shown) has a pair of capillaries (the top ends of which are shown in FIGS. 3A and 3B by a reference numeral 17), an ultrasonic transducer for applying an ultrasonic vibration to the capillaries 17, a movement mechanism for moving the capillaries in a direction of Z-axis, an electric welding torch for forming a gold pre-ball at a front end of the bonding wire and a wire clamping portion.

A process for manufacturing the semiconductor device, in particular a method of wire bonding will now be explained. At first, the package 12 with the lead frames 14 insert-molded and with the semiconductor chip 13 adhered thereto is placed at a fixed position on the bonding station. Then, the positions of the electrodes of the silicon chip 13a as well as the positions of the lead frames 14 of the package 12 are recognized by the image recognition device.

A pre-ball bonding process (pre-bonding process) is thereafter performed, at which the pre-bonding portions 18 are formed on the respective lead frames 14. More in detail, the bonding wire of gold is clamped by the bonding head (capillaries 17), a ball is formed at the front end of the bonding wire as a result of heating by the heating block and the electric discharge, and the capillaries 17 are moved downwardly to a bonding point on the front surface of the lead frame 14, with the bonding wire and the ball at its end while the ball is heated. When the ball reaches the bonding point, the ball is then pressed against the front bonding surface of the lead frame 14 and at the same time vibration is applied to the ball, so that the ball is deformed and connected to the lead frame 14. The capillaries 17 will then be moved upwardly, as shown in FIG. 3A, and the pre-bonding portion 18 firmly connected to the lead frame 14 will be cut and separated from the bonding wire 15. The above pre-ball bonding process is repeated to the other lead frames 14 (four times in this embodiment), so that the pre-bonding portions 18 are formed on all lead frames 14.

After the above mentioned pre-bonding portions 18 are formed on the respective lead frames 14, a primary bonding process is carried on. In this process, a ball is likewise formed at the end of the bonding wire 15 because of the heat and electric discharge, and the capillaries 17 are downwardly moved towards a bonding point (a first bonding point) of the electrode of the semiconductor chip 13. When the ball reaches the first bonding point, the ball is then pressed against the electrode of the semiconductor chip 13 and at the same time vibration is applied to the ball, so that the ball is deformed and connected to the electrode. As above, one end of the bonding wire is connected to the electrode by a thermal compression bonding process. The capillaries 17 will then be upwardly moved, but the bonding wire 15 will not be cut and separated from the ball as in the case of the above mentioned pre-bonding process, namely, the bonding wire 15 is held by the bonding head while the end thereof is kept connecting to the bonded ball on the electrode. The capillaries 17 are further horizontally moved to the lead frame 14 together with the bonding wire 15, while the bonding wire 15 is formed as a loop, as shown in FIG. 1A. When the capillaries 17 reach a certain point, then the capillaries are downwardly moved towards the pre-bonding portion 18 (a second bonding point), at which the bonding wire 15 will be pressed by the capillaries to the pre-bonding portion 18 and the vibration will be likewise applied to bonding wire 15, as shown in FIG. 3B. Accordingly, the bonding wire 15 is at its other end connected to the lead frame 14 (the pre-bonding portion 18) by the thermal compression bonding process.

After the bonding of the bonding wire to the lead frame is completed, the capillaries 17 are again upwardly moved and the bonding wire held by the capillaries will be cut and separated from the bonded portion. The above primary bonding process is repeated to the other electrodes and lead frames 14 (four times in this embodiment), so that electrical connection between the electrodes of the semiconductor chip and the lead frames 14 through the bonding wires 15 is completed.

When the lead frames 14 are insert-molded in the package 12, the top surface of the lead frames 14, namely the second bonding points may be contaminated with resin gas, mold release agent or oil on a surface of mold dies, and soon. Because of the contamination on the surface of the lead frames 14, the bonding performance may be deteriorated.

A high bonding performance is, however, obtained in the present invention, because the bonding wire 15 is bonded to the pre-bonding portion 18 on the lead frame 14. Further, the pre-bonding portion 18 is bonded to the surface of the lead frame 14, a bonding area of which can be made larger than that for a direct bonding of the lead wire to the lead frame, which makes it possible to achieve a high juncture strength between the pre-bonding portion 18 and the lead frame 14 even when the bonding surface of the lead frame is contaminated after the insert-molding. As a result, a high juncture strength between the bonding wire and the lead frame can be obtained.

FIG. 4 shows a result of a tensile test made by the inventors of this invention. A longitudinal axis of FIG. 4 shows a breaking strength of each test. In FIG. 4, “A” means test samples for which a bonding wire is connected to a lead frame by a normal wire bonding before the insert-molding, “B” means test samples for which a bonding wire is connected to a lead frame by a normal wire bonding after the insert-molding, and “C” means test samples in which a bonding wire is connected to a lead frame by the wire bonding of this invention after the insert-molding, namely a pre-ball bonding and a normal wire bonding. As seen from FIG. 4, the breaking strength of the samples “B” is lower than that of the samples “A” due to the contamination on the bonding surface of the lead frame, while the breaking strength of the samples “C” according to the present invention is lower than that of the samples “A” but higher than that of the samples “B”, and the breaking strength of the samples “C” of the present invention is sufficiently high for the actual use of the pressure sensor in the internal combustion engine.

During a course of this invention, the inventors of the present invention made a study for increasing juncture strength between the gold bonding wire 15 and the lead frame 14, in which three different wire bonding methods were reviewed and evaluated. The three methods are firstly a method of reducing the contamination on the lead frame 14 during the insert-mold process, secondly a method of removing the contamination from the lead frame 14 after the insert-molding process, and thirdly a method of increasing juncture strength by changing conditions of the wire bonding of ultrasonic vibration. Those study results will be explained for reference.

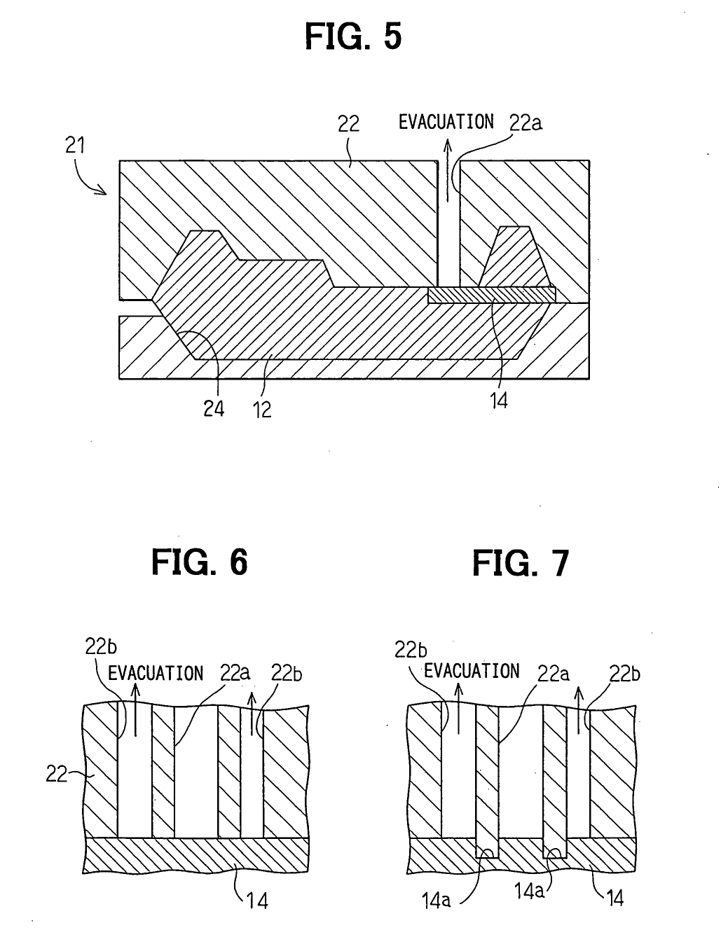

FIG. 5 shows a schematic view of the molding dies 22 and 23 for insert-molding the lead frame 14 into the package 12. For the purpose of reviewing and evaluating the first study, namely the method of reducing the contamination on the lead frame 14, an evacuation passage 22a is provided in the upper die 22, so that resin gas during the molding may be taken away from the die cavity 24. A lower end of the passage 22a is faced to the front surface of the lead frame 14, at which the wire bonding is carried on. It is, however, confirmed by the inventors that the contamination on the surface of the lead frame can not be sufficiently removed.

Accordingly, additional evacuation passages 22b are provided in the upper die 22, as shown in FIG. 6, however, a good result was not obtained. Then, it is considered to provide a concave(s) 14a in the surface of the lead frame 14, so that an end of a wall forming the passage 22a may be inserted into the concave(s) 14a, as shown in FIG. 7. It is, however, necessary to treat a micro fabrication on the surface of the lead frame 14, which may be difficult to treat and increase the manufacturing cost. And therefore, this possibility of FIG. 7 was eliminated from the study. As above, the first study of reducing the contamination from the surface of the lead frame did not propose a better solution than the present invention.

The second study was then made, in which a method of removing the contamination from the lead frame 14 by means of a cleaning method, for example a plasma-cleaning, is evaluated. The plasma-cleaning is a method of cleaning a work, according to which the work is placed in a vacuum chamber, plasma of argon is generated in this vacuum chamber and argon ion is shot against the work, so that the contaminant is blasted off from the surface of the work because of its collision energy. According to this method, it was confirmed that the contaminant can be sufficiently removed and high juncture strength of the bonding wire 15 to the lead frame 14 is obtained.

It is, however, disadvantageous in that an apparatus for this plasma cleaning is expensive and the cleaning process shall be done by batch processing, which make the manufacturing cost higher. A shot blasting process is also possible as an alternative process for removing the contaminant from the lead frame. It is, however, disadvantageous in that surface roughness of the other portions of the package 12, for example a sealing portion, is likewise deteriorated. And therefore, this shot blasting process is eliminated from the further study. As above, a method of removing the contamination from the lead frame 14 by means of a cleaning method, for example a plasma-cleaning, is effective, however this method alone is not recommendable in view of its manufacturing cost.

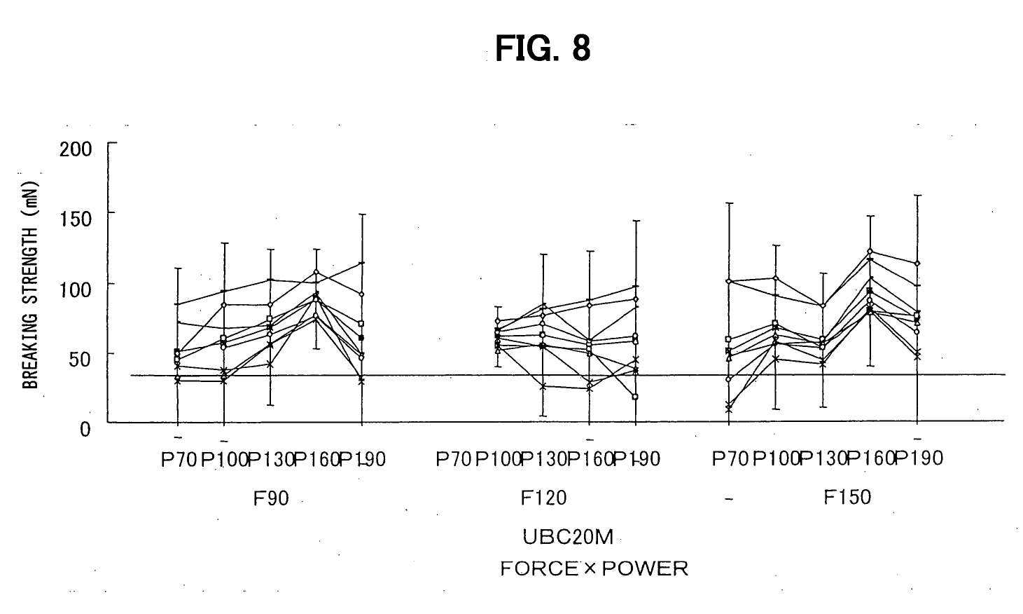

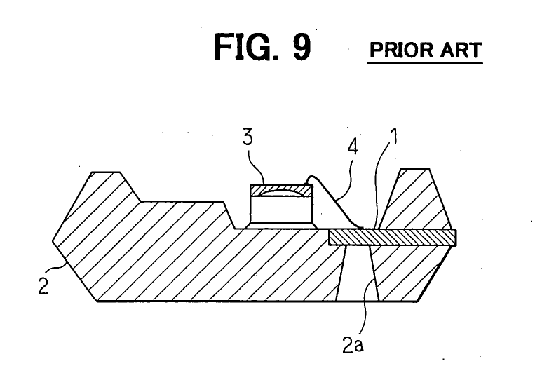

As already explained above, a combination of the ultrasonic wave bonding and thermal compression bonding is used in this invention for bonding the gold bonding wires, while the thermal compression bonding is a main process and the ultrasonic wave bonding is an additional process in this wire bonding method. Under this situation, the third study is made in which conditions of the wire bonding of ultrasonic wave were varied and evaluated. In this study, energy of resonance vibration as well as press power applied to the bonding wires are varied. FIG. 8 shows the result of this study, wherein a longitudinal axis shows a breaking strength. The press power was varied in the three ranges, namely the press power of F90, F120 and F150 was applied to the bonding wires, while the energy of the resonance vibration was varied from P70 to P190, with five different energies of P70, P100, P130, P160 and P190. As seen from FIG. 8, however, the breaking strength was not sufficiently high enough to increase the juncture strength in any of those tests. The breaking strength of the third study is lower than 200 mN, while the breaking strength according to the present invention is higher than 200 mH as seen from FIG. 4.

In the normal wire bonding process of the ultrasonic vibration, the resonance vibration is applied to the bonding wire when the bonding wire comes in contact with the lead frame. It was, however, further tested that the resonance vibration was applied to the bonding wire shortly before the bonding wire comes into contact with the lead wire, under expectation that such pre-vibration may increase the juncture strength due to the friction by the vibration. A good result was not obtained, either.

According to the present invention, the pre-bonding portion is formed on the lead frame 14 and thereafter the bonding wire is bonded to the electrode of the semiconductor chip and to the lead frame at the pre-bonding portion. Because of this pre-ball bonding process, high juncture strength of the bonding wire and the lead frame is obtained, even when there is contaminant on the bonding surface of the lead frame. Furthermore, since this pre-ball bonding can be carried out by the normal wire bonding machine, an increase of the manufacturing cost can be suppressed. Further, according to the invention, a concave is not formed on the back side of the lead frame during the insert-molding process, and thereby it is not necessary to carry on a process for covering such concave by a potting process or the like, which makes the manufacturing cost lower.

In the above mentioned embodiment, although the pre-ball bonding process is done after the lead frame is insert-molded into the package, a cleaning (rinsing) process can be carried out to clean (rinse) the surface of the lead frame 14. This cleaning (rinsing) process, however, can not be such a cleaning process, as plasma cleaning, or shot blasting process, which can sufficiently clean up the surface of the lead frame, because the pre-ball bonding process is afterwards done. In other words, any cleaning (rinsing) process, which is low in cost, can be adopted to the present invention.

Finally, although the present invention is applied to the semiconductor pressure sensor device in the above embodiment, it can be also applied to any other semiconductor device, such as acceleration sensor and so on, in which semiconductor chip is connected to lead frames by means of wire bonding process.

What is claimed is:

1. A method of wire bonding for a semiconductor device, in which a lead frame is insert-molded into a package of resin, a semiconductor chip is mounted onto the package, and a gold bonding wire connected between an electrode of the semiconductor chip and the lead frame, wherein the method comprises:
a step of pre-ball bonding, in which a pre-ball is formed from the gold bonding wire and the pre-ball is cut from the bonding wire so that a pre-bonding portion is formed on the lead frame; and
a step of wire bonding, in which the gold bonding wire is bonded to the electrode of the semiconductor chip at a first bonding point and then to the pre-bonding portion at a second bonding point.

2. A method of wire bonding according to claim 1, wherein the method further comprises a step of cleaning the bonding surface of the lead frame before the step of pre-ball bonding.

3. A method of wire bonding for a semiconductor device comprising:
a step of insert-molding a lead frame into a package of resin;
a step of mounting a semiconductor chip onto the package;
a step of forming a pre-ball from a gold bonding wire at a front end of capillaries of a bonding machine;
a step of forming a pre-bonding portion on a bonding surface of the lead frame, by a combination process of an ultrasonic vibration bonding and a thermal compression bonding process, in which the pre-ball is pressed and fixed to the lead frame and then the pre-ball will be cut and separated from the bonding wire;
a step of bonding one end of the gold bonding wire to an electrode of the semiconductor chip by the combination process; and
a step of bonding the other end of the gold bonding wire to the pre-bonding portion by the combination process.

4. A semiconductor device comprising:
a package of resin into which a lead frame is insert-molded;
a semiconductor chip mounted on a front surface of the package; and
a gold bonding wire connected at its one end to an electrode of the semiconductor chip and at its other end to the lead frame,
wherein a pre-bonding portion is formed from the gold bonding wire and fixed onto the lead frame, and
wherein one end of the gold bonding wire is connected to the pre-bonding portion.

5. A semiconductor device according to claim 4, wherein
a back surface of the lead frame is completely embedded in the molded package.

6. A semiconductor device having
a resin molded package into which a metal lead frame is insert-molded;
a semiconductor chip mounted on a front surface of the resin molded package; and
a gold bonding wire connected at its one end to an electrode of the semiconductor chip and at its other end to the metal lead frame,
wherein a pre-bonding portion is formed from the gold bonding wire and fixed onto the metal lead frame by means of wire bonding process, which comprises an ultrasonic wave bonding and a thermal compression bonding;
wherein one end of the gold bonding wire is connected to the electrode of the semiconductor chip by the wire bonding; and
wherein the other end of the gold bonding wire is connected to the pre-bonding portion by the wire bonding.
